(19) United States
(12) Patent Application Publication
(10) Pub. No.: US 2006/0230002 A1
(43) Pub. Date: Oct. 12, 2006

(54) Utility usage evaluation system and method

(75) Inventors: Geoffrey William Bennett, Wellington (NZ); Stuart Arthur Sheppard, Wellington (NZ)

Correspondence Address: SEED INTELLECTUAL PROPERTY LAW GROUP PLLC, 701 FIFTH AVE, SUITE 6300, SEATTLE, WA, 98104-7092, US

(73) Assignee: Energy and Technical Services Limited, Wellington (NZ)

(21) Appl. No.: 10/519,729

(22) PCT Filed: Jun. 30, 2003
(86) PCT No.: PCT/NZ03/00136

§ 371 Date: Mar. 10, 2006

(30) Foreign Application Priority Data
Jun. 28, 2002 (NZ) 519877

(51) Int. Cl. G01R 21/133; G01R 11/56; G06F 17/00

(52) U.S. Cl. 705/412

(57) ABSTRACT

The invention provides a method of evaluating utility usage of an organization that involves storing in computer memory data representing one or more facilities or processes operated by the organization and storing in computer memory data representing one or more utility sources, each facility or process using one or more of the utility sources. The invention calculates the utility consumption from each utility source for at least one facility and generates a report detailing utility usage of one or more of the facilities, or part thereof, of the organization The invention also provides a related utility usage evaluation system.

### BACKGROUND OF THE INVENTION

1. Field of the Invention

The invention relates to a utility usage evaluation system and method, particularly but not solely designed for measuring the energy and environmental efficiency of a facility or process and comparing it to benchmarks established from other facilities and processes.

2. Description of the Related Art

Environmental issues are becoming ever more important in the running and administration of processes, facilities and estates. Good information and benchmarks can greatly aid in identifying opportunities for improving efficiency and achieving cost savings. Such information is good for an organization's bottom line and good for the organization's country as a whole.

There are several tasks which must be performed when conducting a benchmarking exercise for an organization to ensure that valid comparisons are being made. These tasks include selecting a subject area, defining a process to be benchmarked, identifying potential benchmarking partners and identifying data required, the sources and appropriate methods of collection. A data analysis phase includes collecting the data and selecting benchmarking partners, determining the performance gap, establishing the difference in the process, and targeting future performance. Many of these tasks, such as identifying benchmarking partners, can be very time-consuming and difficult.

Japanese patent specification JP 2002-007523 to Osaka Gas Co Limited entitled “Evaluation System for Consumer Energy Facility” describes the comparison of energy facilities. These energy facilities include air conditioning equipment, hot water supply, gas turbines, gas engines, absorption-type cold calorifier, fuel cells, co-generation plants, combined cycle equipment, etc. A facility is described in this patent specification as a particular electrical device. These specific devices are compared with benchmarks to simulate energy usage for overall site usage. The specification does not describe the benchmarking of one facility, which could include several devices, with other like facilities.

### BRIEF SUMMARY OF INVENTION

In broad terms in one form the invention comprises a method of evaluating utility usage of an organization comprising storing in computer memory data representing one or more facilities operated by the organization; storing in computer memory data representing one or more utility sources, each facility using one or more of the utility sources; calculating the utility consumption from each utility source for at least one facility; and generating a report detailing utility usage of one or more of the facilities, or part thereof, of the organization.

In broad terms in another form the invention comprises a method of evaluating utility usage of an organization comprising storing in computer memory data representing one or more processes operated by the organization; storing in computer memory data representing one or more utility sources, each process using one or more of the utility sources; calculating the utility consumption from each utility source for at least one process; and generating a report detailing utility usage of one or more of the processes, or part thereof, of the organization.

In broad terms in another form the invention comprise a utility usage evaluation system comprising a client data store in which is stored data representing one or more facilities operated by an organization, and data representing one or more utility sources, each facility using one or more of the utility sources; a utility consumption calculator configured to calculate the utility consumption from each utility source for at least one facility; and a report generator configured to generate a report detailing the utility usage of one or more of the facilities of the organization.

In broad terms in another form the invention comprises a utility usage evaluation system comprising a client data store in which is stored data representing one or more facilities operated by an organization, and data representing one or more utility sources, each process using one or more of the utility sources; a utility consumption calculator configured to calculate the utility consumption from each utility source for at least one process; and a report generator configured to generate a report detailing the utility usage of one or more of the processes of the organization.

### BRIEF DESCRIPTION OF THE SEVERAL VIEWS OF THE DRAWINGS

Preferred forms of the utility usage evaluation system and method will now be described with reference to the accompanying figures in which:

FIG. 1 is schematic representation of typical organizations to be evaluated in accordance with the invention;

FIG. 2 shows a block diagram of a preferred Internet-based system in which the present invention can be implemented;

FIG. 3 shows a preferred system architecture of a client or web server from FIG. 2;

FIG. 4 shows a data capture process in accordance with the invention;

FIG. 5 shows another preferred form data capture process for calculating an energy map;

FIG. 6 shows sample data obtained by one step of the process of FIG. 5;

FIG. 7 shows further sample data generated from a step in the process of FIG. 5; and

FIGS. 8-17 show preferred form fields for the client data store and/or benchmark database shown in FIG. 2.

### DETAILED DESCRIPTION

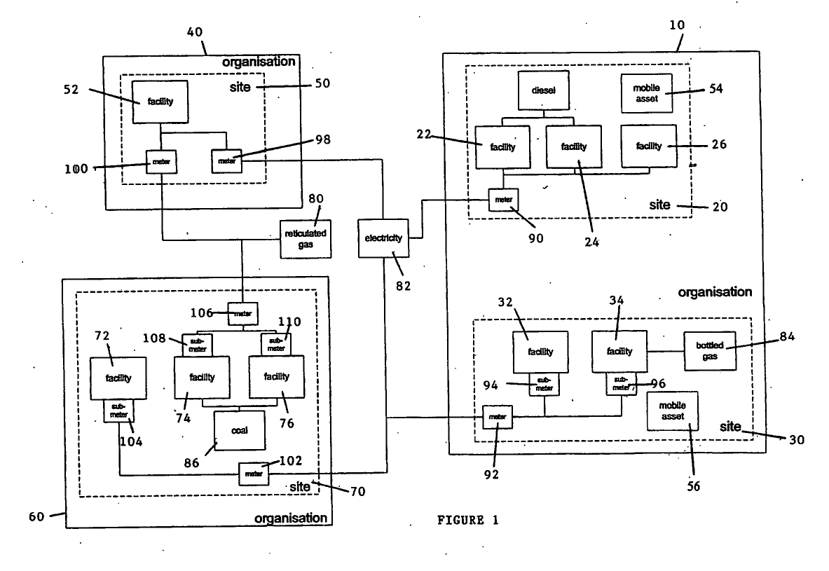

FIG. 1 illustrates typical organizations which the invention is configured to evaluate. Organization 10, for example, could include one or more sites, for example site 20 and site 30. Each site is generally confined to a geographic area and could include one or more individual facilities or processes, for example, site 20 includes facility 22, 24 and 26 whereas site 30 includes facility 32 and 34. Where the organization is a university, each university campus would be considered to be a site, having one or more individual facilities, for example buildings. Organization 40 could include just one site 50 which in turn could include just one facility 52.

Organizations could have associated with them one or more mobile assets, for example mobile asset 54 and mobile asset 56. Mobile assets include vehicles and vehicle fleets. These assets use utilities such as petrol, diesel and oil. Organizations could also have associated with them one or more processes. One example of a process is machinery or plant setup, for example a boiler plant. A process is able to provide services to occupied areas, such as facilities. Some processes could be located within a facility (for example, boilers) that provide services to other facilities. Further examples of processes include mixing machines and crushers.

Organization 60 could include one site 70 and this site could include facilities 72, 74 and 76. Individual organizations could operate in one or more industries, for example manufacturing type industries or processing type industries.

Each site could draw energy from one or more utility sources, for example networked energy sources such as reticulated gas 80 or electricity 82 or on-site energy sources such as bottled gas 84 or coal 86. It is also envisaged that energy sources could include diesel, on-site solar generation, biomass, and other energy sources. Further utility sources could include water, petrol and oil. Some of the examples referred to in the specification relate to energy consumption although it will be appreciated that the consumption or usage of any utility could be measured.

A utility could also include measurement of waste products or by-products produced by an organization. Such utilities include waste streams, for example waste water, sewerage and rubbish produced by an organization.

It is envisaged that each site may have different metering facilities. Site 20, for example, could include meter 90 to identify the consumption of electricity from electricity source 82. In this case, site 20 has no sub-metering and so meter 90 measures the energy coming onto the site 20 but not its distribution around different facilities 22, 24 and 26. In contrast, meter 92 calculates the consumption of electricity from energy source 82 for site 30. Meter 92 is connected to sub-meters 94 and 96 to calculate the energy consumed by facilities 32 and 34 respectively.

Site 50 could include meter 98 measuring consumption of electricity from energy source 82 for site 50. Site 50 could also include meter 100 for measuring consumption of gas from energy source 80.

Site 70 could include meter 102 for measuring consumption of electricity from energy source 82. Site 70 includes limited sub-metering. The total energy consumed by the combination of facilities 72, 74 and 76 are measured by meter 102. Sub-meter 104 measures the consumption of facility 72 only.

Meter 106 measures the consumption of energy from energy source 80 for facilities 74 and 76 and sub-meters 108 and 110 measure the individual consumption of facilities 74 and 76 respectively.

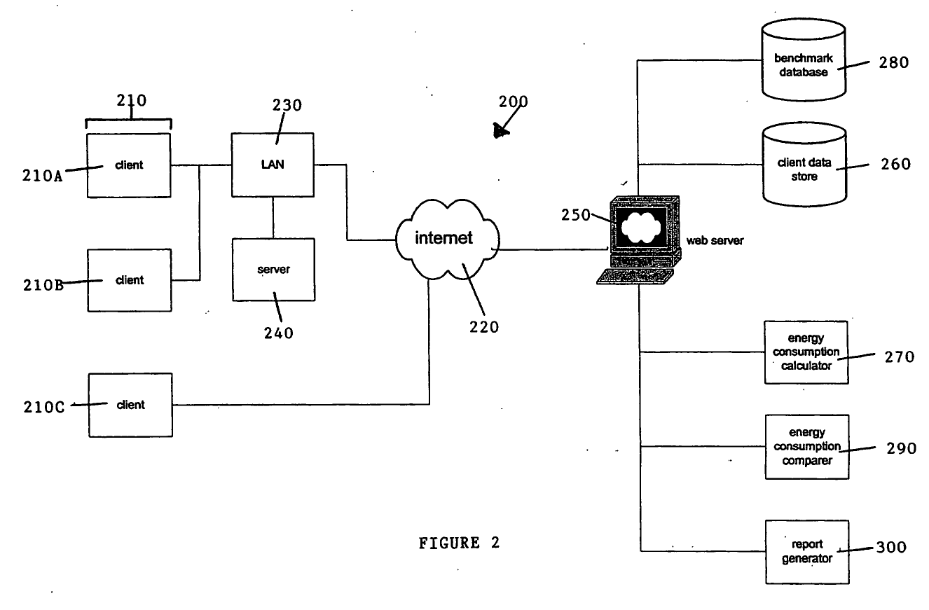

FIG. 2 illustrates a block diagram of the preferred Internet-based system 200 in which the present invention may be implemented. The system includes one or more clients 210, for example clients 210A, 210B and 210C, which each may comprise a personal computer or workstation which will be described below. Each client 210 is interfaced to the Internet 220 and is configured to enable a user access to web browsing software. As shown in FIG. 2, each client 210 could be connected directly to the Internet 220 with a suitable dial-up connection or could be connected through a local area network or LAN. Client 210C is shown as connected to the Internet 220 with a dial-up connection. Clients 210A and 210B, on the other hand, are connected to a network 230 such as a local area network or LAN. The network 230 could be connected to a suitable network server 240 and communicate with the Internet 220 as shown.

The system 200 also includes a suitable web server 250 connected to the Internet 220 as shown in FIG. 2. The web server 250 preferably comprises a personal computer or workstation operating under the control of suitable software. Connected to web server 250 is a client data store 260. Software operating on the web server 250 is configured to obtain utility or energy consumption data from a client 210 and to store this consumption data in the client data store 260. The system 200 also includes a utility or energy consumption calculator which in one form could be a software program which is configured to calculate utility or energy consumption of a client organization from data supplied from the client 210. A benchmark database 280 stores utility consumption data from several different types of facilities, processes, and mobile assets belonging to an organization and a utility or energy consumption comparer 290 compares consumption data relating to client facilities, processes and/or mobile assets from the client data store 260 and the utility or energy consumption calculator 270 with data stored in the benchmark database 280. A report generator 300 generates reports on energy consumption ready to transmit to the client 210.

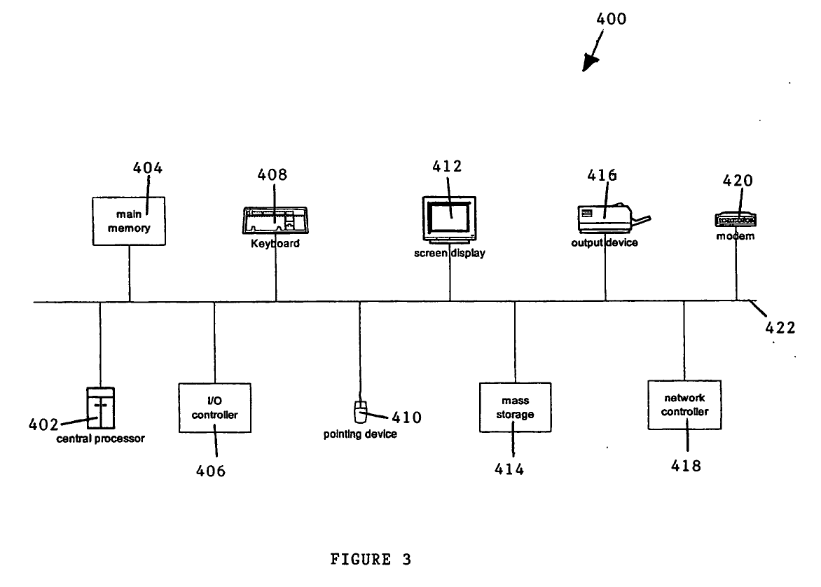

FIG. 3 shows the preferred system architecture of a client 210, or web server 250. The computer system 400 typically comprises a central processor 402, a main memory 404, an input/output controller 406, a keyboard 408, a pointing device 410 for example a mouse or touch sensitive screen, a display or screen device 412, a mass storage memory 414, for example a hard disk, floppy disk or optical disc, and an output device 416, for example a printer. The computer system 400 could also include a network interface card or controller 418 and/or a modem 420. The individual components of system 400 could communicate through a system bus 422.

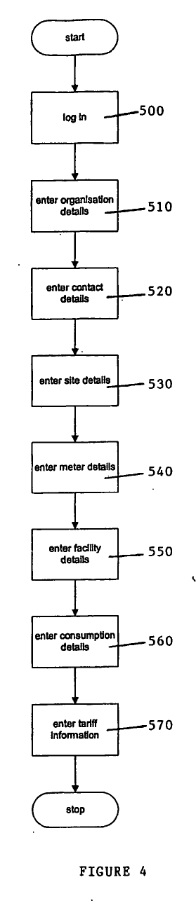

FIG. 4 illustrates the data capture process for a user wishing to benchmark one or more facilities. The user first completes a log-in screen 500 requiring entry of a user ID and password for example. It is envisaged that the client data store 260 store data relating to more than one user and that the log-in screen permits a user to be uniquely identified and that the user may only access data relating to the user's own organization.

The user is then required to enter organization details. On first use of the system, it is envisaged that the user will need to complete details about the user organization. This is fairly basic information and includes information such as website address, postal address, the type of organization and so on. It is envisaged that some of this information will already have been entered by the operator of the web server when setting up the user account. In a preferred form, the user is able to change data already entered in the case where organization details have changed, for example through a merger process.

The user may also need to enter contact details 520. In one preferred form there are three types of contacts, namely primary, basic and read only. Each organization has one primary contact which is the person with whom the usage agreement has been made and will be the only person authorized to approve new users being added to the system. A basic user has access to all the information for the organization and can add, update and change information as necessary and download all reports. The third category, read only, is for a user who can only look at the information and download reports. A read only user is not able to update or change any information. A read only category could be useful for an organization that does not want people from outside the organization to modify confidential information.

The user then enters site details 530 in order to identify all the sites run by a user organization. If the site has several different facilities, processes, or mobile assets, the user could be provided with an option to create an energy map of the site which lists all the facilities, processes, and mobile assets, all the meters and energy sources and then correlates them. An energy map could be particularly important where there is some sub-metering on the site. The energy map is described further below.

The user then enters meter details 540. The meter for the purposes of the invention could be either the actual metering equipment in place on reticulated electricity and gas such as that shown in FIG. 1, or alternatively could include a theoretical point to measure the use of un-metered energy sources such as diesel, coal or bottled gas.

The invention permits an unlimited number of meters per facility or processes to account for all energy sources, for example electricity, gas, diesel for generators and so on. The invention also allows for an unlimited number of facilities or processes per meter to allow for sites with multiple facilities and/or processes and limited sub-metering which is described below.

The configuration of which facilities and processes are supplied from which meters may change as new meters are installed and old meters are removed. The invention envisages this arrangement by having a start and end date for each specific facility or process and meter relationship.

It is also envisaged that there are two levels of meters as described above in FIG. 1, for example supply meters and sub-meters. Supply meters are used to aggregate information for the site in total, whereas the sub-meters are used to measure energy usage at individual facilities and processes.

A single facility or process site is a site which has only a single facility or process. All energy use at that site is assigned to that facility or process. Each meter for the site will only be associated with a single facility or process when entered into the application. Site 50 from FIG. 1 is an example of a single facility site.

A multiple facility and/or process site could include complete sub-metering, no sub-metering or limited sub-metering. With complete sub-metering, there are several different facilities and/or processes located at that site but sufficient sub-metering to identify the energy consumed by each individual facility and process. Site 30 is one example of a multiple facility site with complete sub-metering. In this case, the user would enter each individual facility and/or process much as the user would for a single facility or process site, and creates a relationship between the meter and the facilities and/or processes.

In another case, a multiple facility and/or process site may have no sub-metering. The only meters on the site measure energy coming onto the site but not its distribution around different facilities and/or processes. Site 20 is an example of a multiple facility site with no sub-metering. In this case, it is necessary to create a relationship between each meter and all the facilities and/or processes that use that energy. It is also necessary to determine a division of this energy use across the facilities and/or processes. This division could be on the basis of proportion of total floor area, volume of the facility, or some other basis.

In a further case, a multiple facility and/or process site may have limited sub-metering. Site 70 is an example of such a site having a meter 102 covering facilities 72, 74 and 76 but having a sub-meter 104 only for facility 72. It is best in this case to create an energy map described below so that a local apportionment of energy use across the various facilities and/or processes can be determined.

The user also enters facility or process details 550. The first component of this information is general information on the facility or process. This includes information such as facility or process name, when it was built, what type of facility or process it is and so on. The second component deals with the structure and utilization of the facility or process being benchmarked, essentially the size of the facility or process, the materials from which a facility is constructed, and the frequency of use of the facility or process.

The invention permits an unlimited number of records for each facility or process containing this information. This is because usage patterns can vary quite markedly in some facilities and processes. In addition, renovations and refurbishments may alter some of the information contained in the record. In these cases, it is necessary to maintain a historical record of the utilization to match the historical energy consumption.

The frequency with which these records should be updated will match the variability of the usage of the facility or process. A facility or process with very stable usage will need fairly few updates, but a facility or process where usage varies quite considerably on a regular basis may need relatively frequent updates, for example monthly or more frequently. Ultimately, the quality of the benchmark obtained for each facility or process will be determined by the quality and accuracy of the information contained in the database.

The user may then enter consumption details 560. The invention is configured to accept three main formats of consumption information. Aggregated information for any period of time, for example an annual figure, monthly figures and so on, can be entered by the user. For most sub-meters and energy sources, this sort of information will be all that is available.

Information broken down by time periods as well as dates can also be input. This allows for information from data loggers measuring half hourly blocks of consumption for reticulated electricity and gas. It also allows for profile consumption to be input which can be measured by month, business day/non-business day or time block.

The user may optionally enter tariff or pricing information 570. The entry of this information will allow the estimation of potential savings to be made through efficiency measures to be based on actual tariffs rather than an estimated national average price. Pricing is broken into three components, fixed costs, demand costs and unit costs.

Demand costs are expected to relate mainly to reticulated gas and electricity. In the case of electricity, this would be for demand charges per KVA. For gas, it would relate to the MDQ overruns.

Fixed costs also relate mainly to electricity and gas. These are costs imposed regardless of actual consumption. They may be in the form of metering charges, account management charges, and connection charges.

Unit charges apply to all energy sources. This is the price paid per unit supplied. In the case of electricity, it is the per kilowatt price. For reticulated gas it is per GJ. For all other sources it is per volume/weight of the source, for example per liter of diesel, kilogram of coal.

It is envisaged that all prices be in a currency, for example dollars, exclusive of sales tax and after any discounts, for example direct debit, prompt payment and the like have been applied.

The fixed charges and demand charges inputs use very similar interfaces. The unit price interface is similar to that used for the consumption information.

It is envisaged that the data entered by the user be specific for the organization. Information to be entered for an industrial process will generally be unique to different types of processes, and will be customizable by the user. Mobile asset information, for example vehicle fleet information, will include information such as engine size, urban/open road use, emissions, travel distance and so on.

Following data entry by the user, the data is stored in computer memory in the client data store 260. The resulting client data store will include data representing one or more sites operated by the organization, data representing one or more facilities and/or processes, and data representing one or more energy sources.

As described above, in some circumstances it may be necessary to develop an energy map for a site if there are several facilities and/or processes located there, if the metering of energy for these facilities and/or processes is not straightforward.

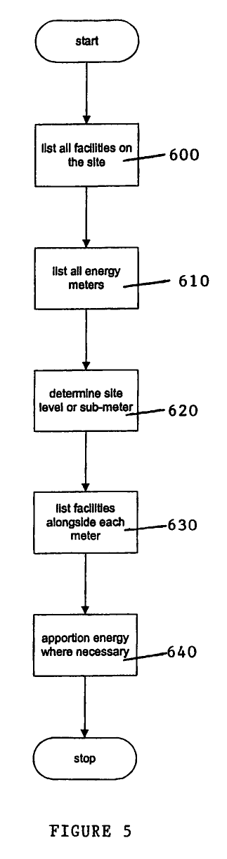

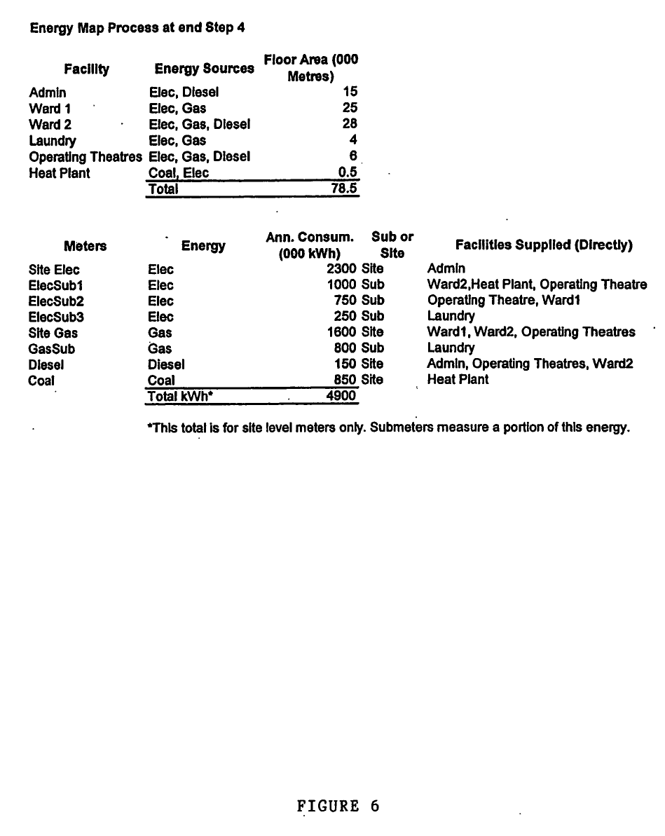

There are a large number of possible metering configurations that might be found on a multiple facility and/or process site, and determining the configuration and entering it into the application can seem a daunting task. FIG. 5 illustrates one method of entering this information in a simple logical manner in accordance with the invention.

The first step 600 is to list all facilities and processes on the site. It is best to list each type of energy used by these facilities and processes, for example electricity, gas, on-site generation, etc. Additionally for each facility and process, it is best to list the variable by which the consumption would be calculated on a pro-rata basis. One example could be floor area.

The next step is to list all energy meters 610 for electricity and gas. The energy meters are added to the list of all other energy sources, such as solar generation, diesel for generators, coal, etc. The annual consumption for each meter or energy source is then calculated.

It is then necessary to determine 620 whether the meter is a supply level or sub-meter. A supply level meter measures the energy coming onto the site. A sub-meter measures the distribution of this energy around a specific part of the site.

Alongside each meter, all the facilities and/or processes that are supplied by the meter are listed 630. The only facilities and/or processes that should be entered against the supply meters are those that are directly supplied by the supply meter.

In cases where a meter/energy source supplies more than one facility and/or process, it is necessary to apportion the energy consumed across the facilities and/or processes 640. This apportionment can be based upon actual data, for example from energy audits measuring supply directly into the facility, or from a pro-rata approach. It will be appreciated that the pro-rata approach is less accurate, but will enable some general comparisons to be performed.

If there is a heat plant that supplies several facilities and/or processes, it is necessary to include this in the energy calculations when determining proportions of consumption from meters to facilities and processes. This should only use the energy used for heating.

The figures calculated should also be checked manually. For example, where a facility or process is supplied by more than one meter for an energy source, and where those meters also supply other facilities and/or processes, it may introduce an error into a simple pro-rata calculation and some adjusting may be appropriate.

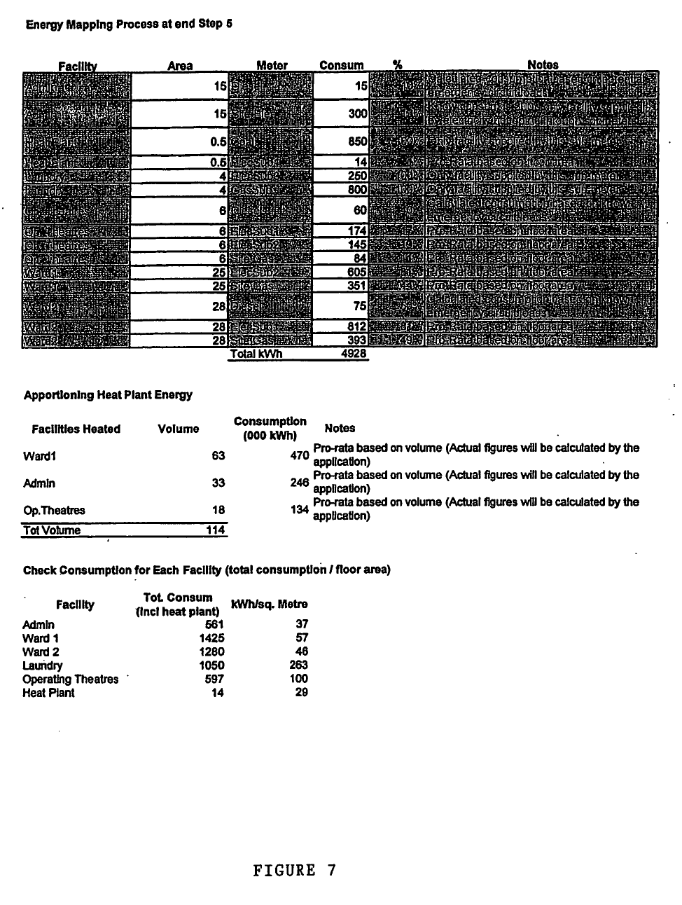

FIG. 6 illustrates the data compiled at the end of step 630 from FIG. 5 and FIG. 7 shows the data compiled at the end of step 640 from FIG. 5.

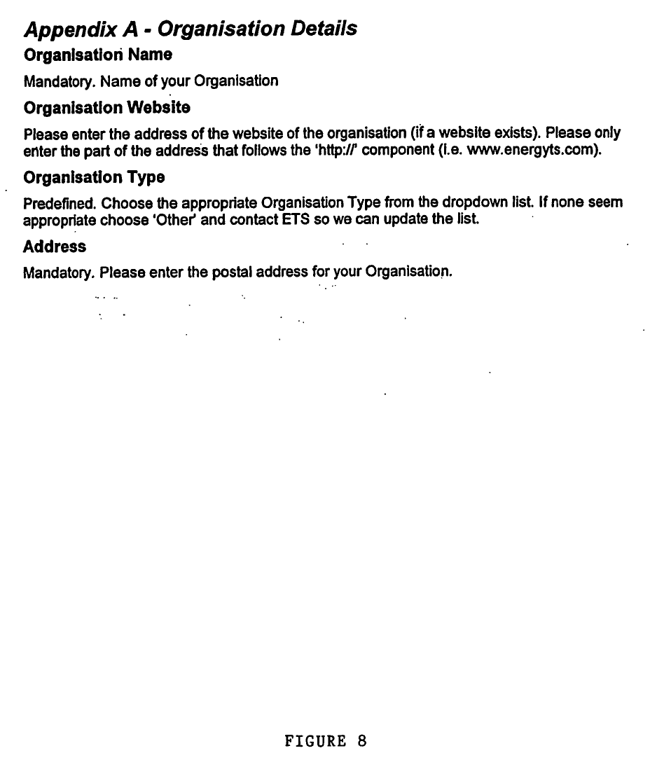

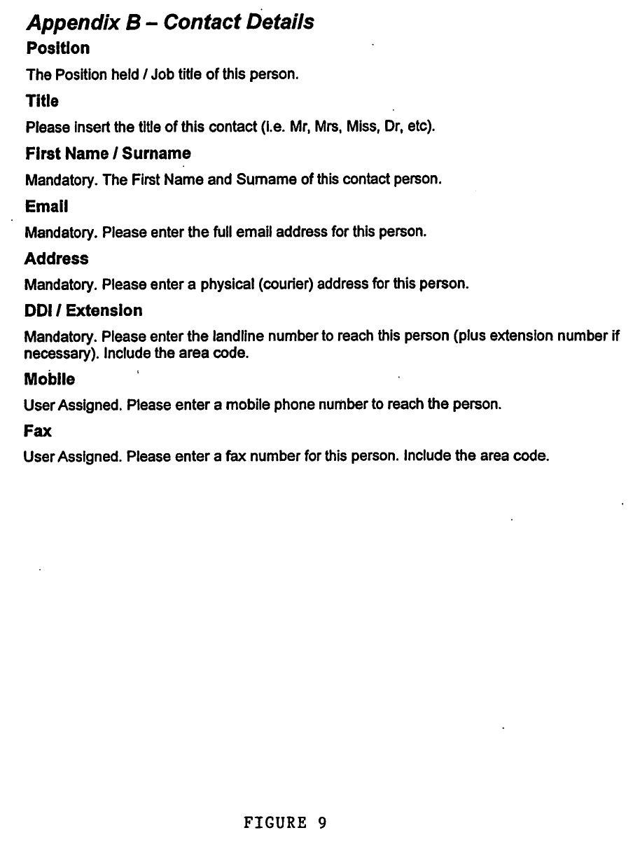

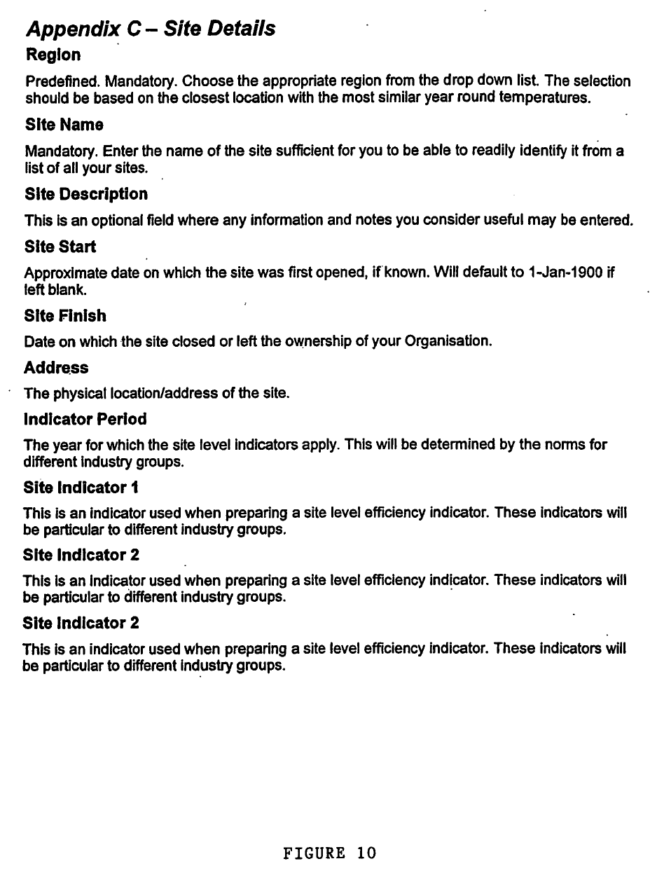

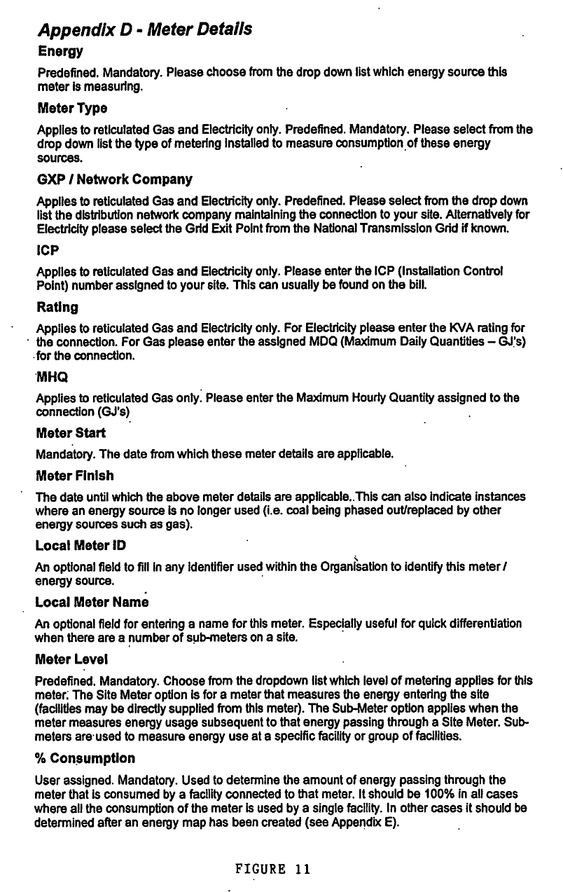

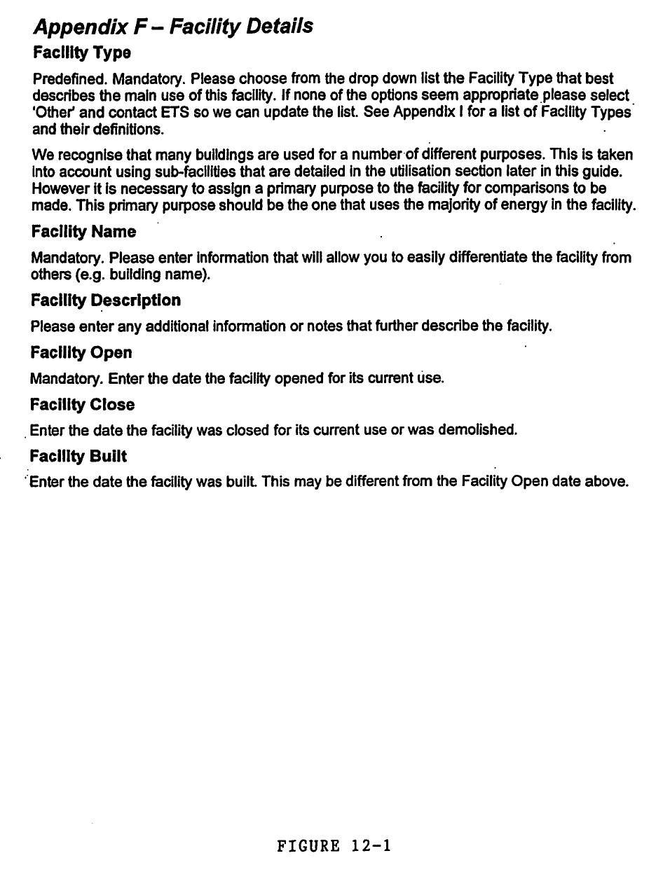

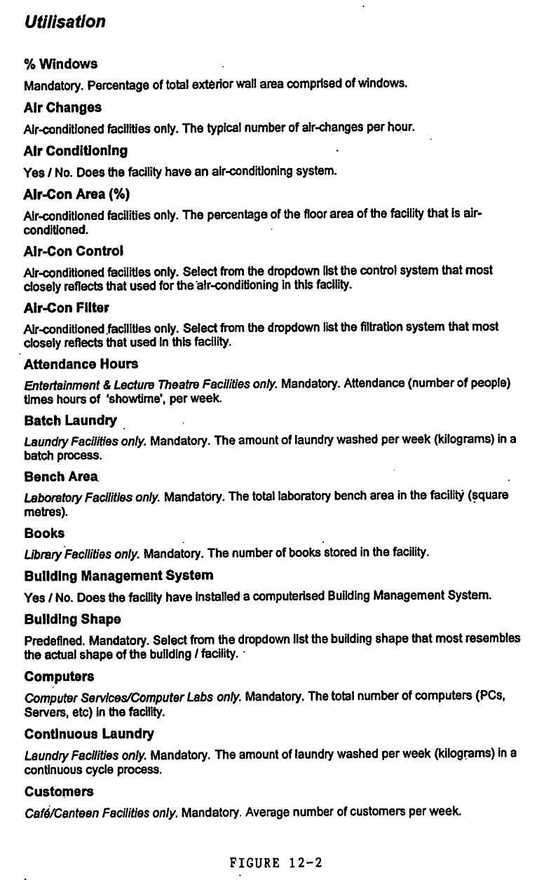

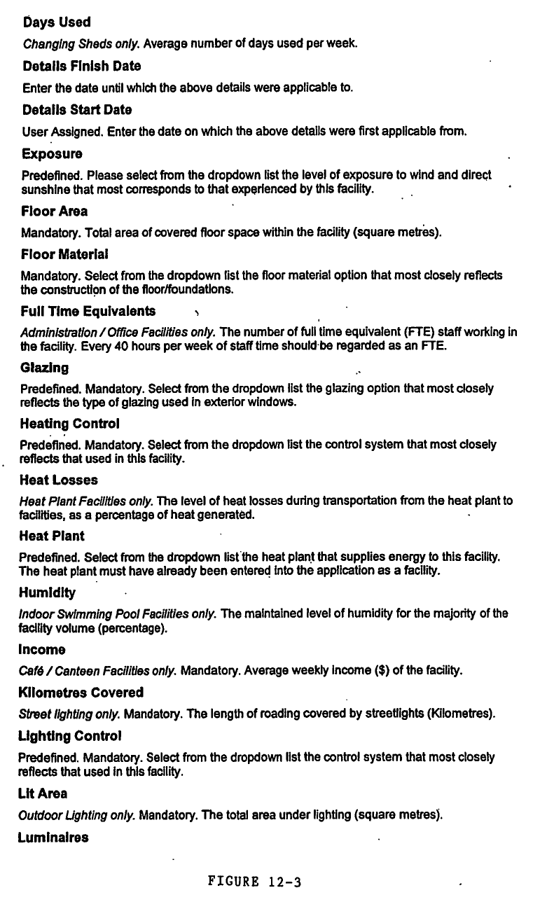

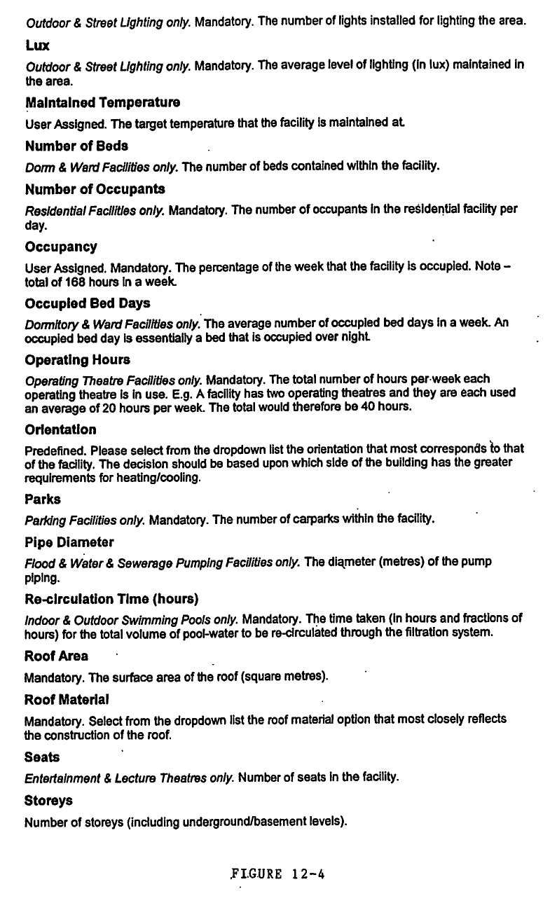

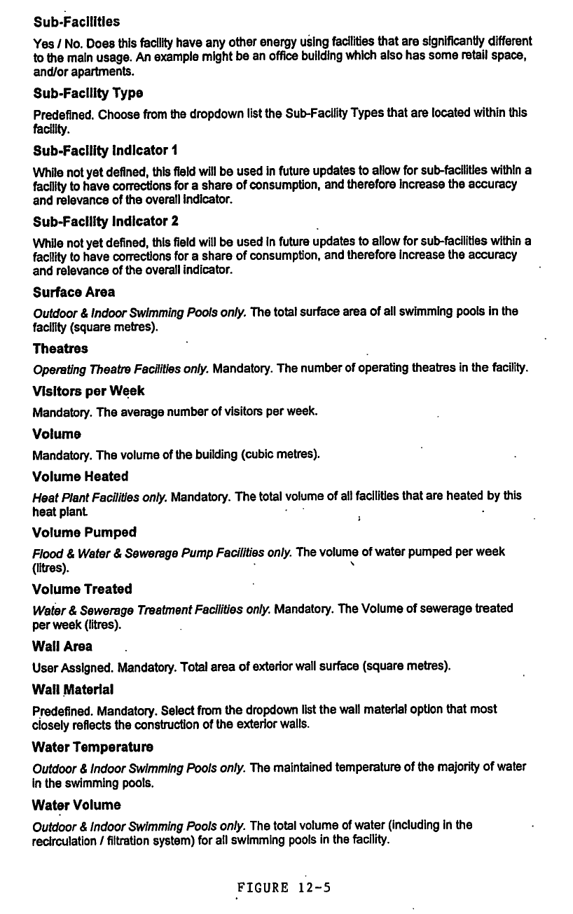

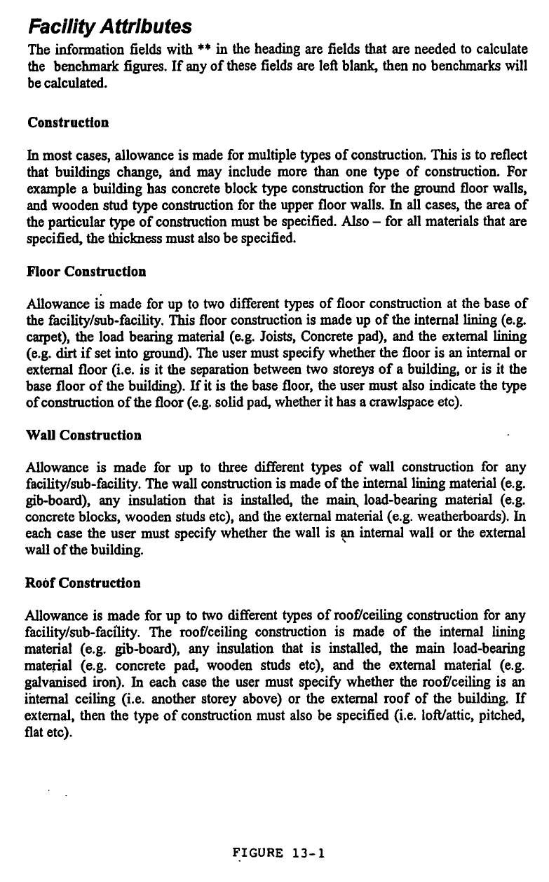

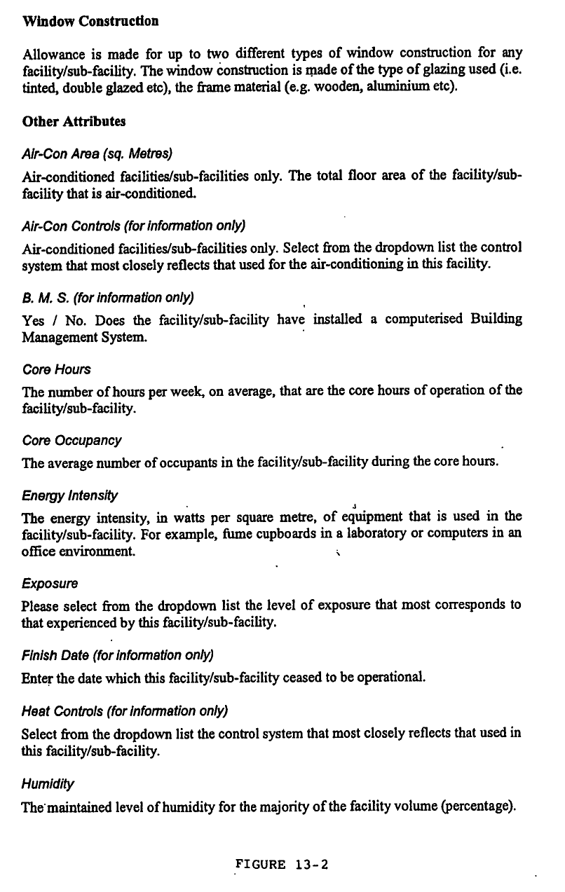

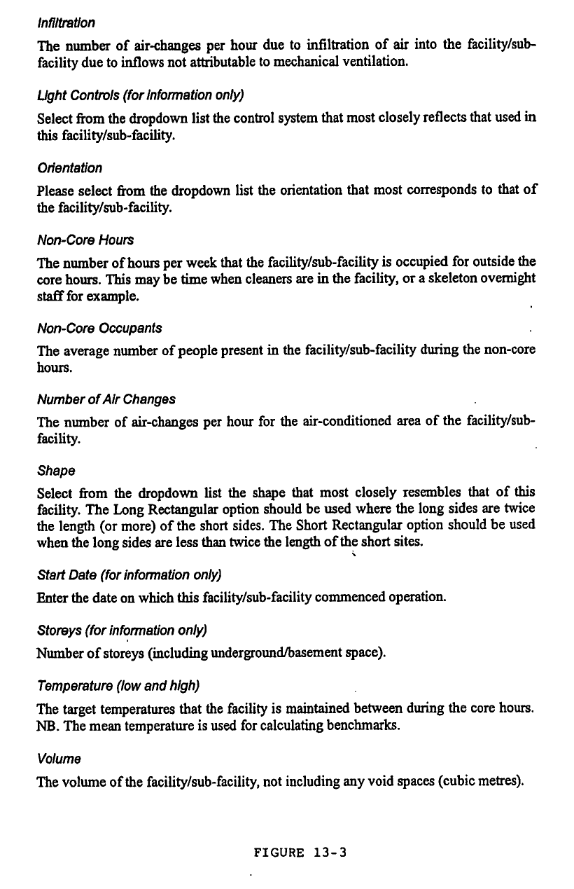

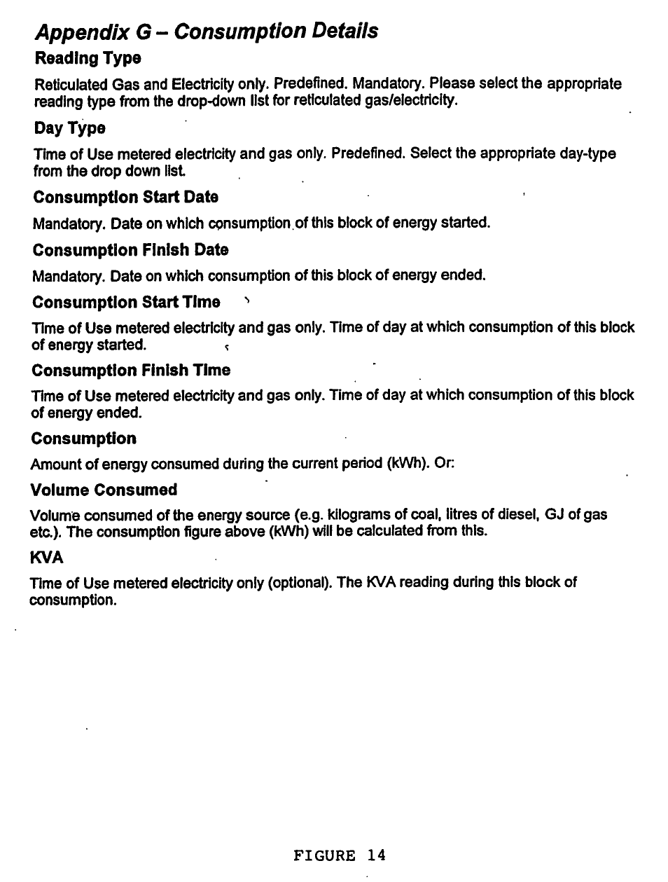

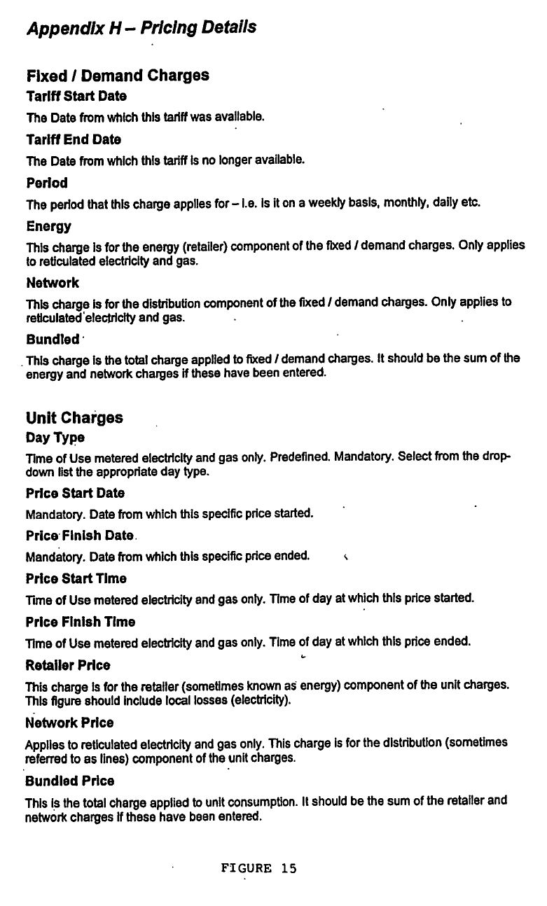

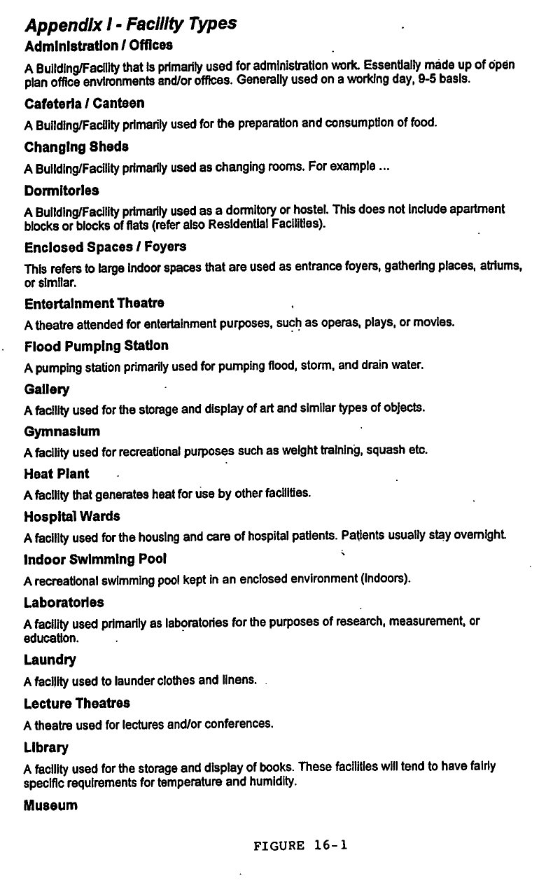

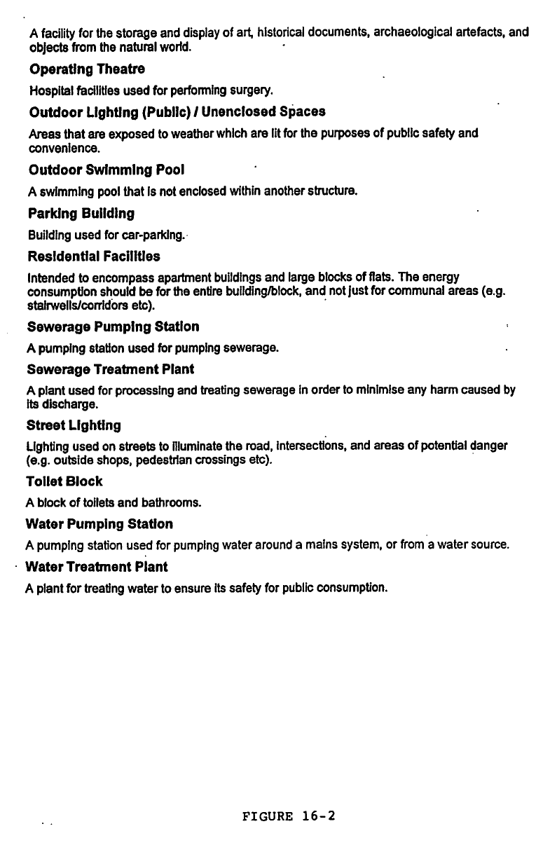

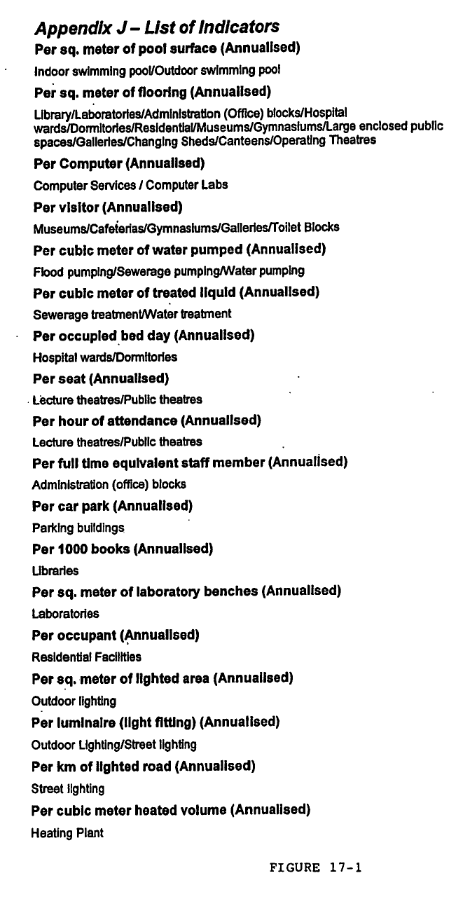

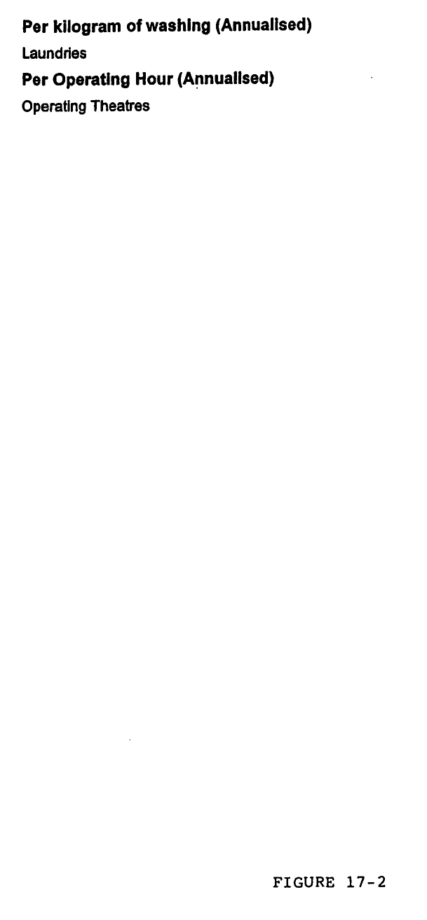

Preferred fields for the client data store 260 and/or benchmark database 280 are shown in FIGS. 8-16. FIG. 8 illustrates example organization details, FIG. 9 contact details, FIG. 10 site details, FIG. 11 meter details. FIGS. 12-1, 12-2,12-3, 12-4 and 12-5 illustrate preferred form facility details, FIGS. 13-1,13-2 and 13-3 illustrate alternative preferred form facility attributes, FIG. 14 illustrates consumption details, FIG. 15 illustrates pricing details, FIGS. 16-1 and 16-2 illustrate facility types and FIGS. 17-1 and 17-2 illustrate a list of indicators.

The invention is configured to calculate utility consumption from each utility source for at least one of the facilities or processes and to generate a report dealing with the utility usage of one or more of these facilities and/or processes of the organization. In this sense, the invention is configured to report on a facility as a whole rather than breaking it down into component parts.

The report can optionally provide utility usage data of part of a facility, for example a sub-facility and possibly also individual processes and assets within that sub-facility or facility. The division of facilities into parts can be along departmental lines, business clusters, different types of use, individual processes, or different tenants. It is envisaged that the user be provided with flexibility in selecting how a report is to provide data on parts of facilities. Should a user choose to break the building down into sub-facilities, utility consumption would also be calculated at the sub-facility level for measurement and benchmarking.

The reporting of sub-facilities enables customized indicators in addition to standard system set indicators. These customized indicators allow a user to measure energy consumption at a facility using an indicator that is meaningful only to their organization, for example organization specific. The indicator could be useful for targeting and monitoring utility consumption over time as well as in determining how successful a performance contract could be. It is anticipated that customized indicators would become standard system indicators where there are several organizations using a similar customized indicator, or where a group of organizations indicates they would like to add a new system indicator.

Standard system indicators can also be used for targeting and monitoring. In this way the user could set a target level of consumption or cost, or energy CO₂ emissions, and track progress towards or away from this target level. Alternatively, the user could set a base level of consumption and monitor an organization's progress in relation to this base level. This allows for targeting and monitoring processes in parallel to benchmarking the facility, process, or mobile asset against other facilities, processes, and mobile assets in a sample. The invention could be used as a device to manage and monitor climate change and greenhouse gas production schemes.

The invention can be used when benchmarking and monitoring profiled processes. In many of these situations, the consumption is unmetered. One example is street lighting in which the consumption may be based upon a calculation of the installed wattages of all the lights multiplied by the hours of service. Analysis and benchmarking of such profiled sites would include assessment of the duration over which they should be operating, and benchmarking against other processes with the same type of profiled use. Benchmarking profiles can also be created by using other processes where actual consumption data may be available and extending these patterns of use, if any, into other assets where consumption data may not be available.

It is also envisaged that reports be generated enabling benchmarking across different types of facilities, for example comparing a hospital ward with a hotel. The user is relied on to assess and enter a correcting factor that correlates to the energy intensity of the facility/sub-facility in watts per square meter. The energy intensity comprises the equipment that is used to meet the facility type operating requirements. This energy intensity would include devices such as fume cupboards in laboratories and computers in computer laboratories/services. The energy intensity will also allow for occasions when equipment is turned off as a normal part of the operation of the facility, for example lights being turned off in a movie theatre.

The correcting factor will be time and use related, for example two core hours, and would have either a negative or a positive impact. For example, if the building has equipment operating in winter, then it will have a positive impact as less heating from the building systems will be needed but in summer it will have a negative impact, for example additional cooling capacity from the chillers.

One advantage of the above data being kept up to date, and optionally supplemented with data supplied automatically from utility retailers, is that a continuous audit is being performed on the facility, sub-facility, process and/or mobile asset.

It is also envisaged that measurement and benchmarking of utility use be carried out at levels higher than that of individual facilities. In this way, subordinate utility consumption information, for example from facilities, processes and/or mobile assets is aggregated into higher levels.

One example of such a high level is site and organization level management measurement and benchmarking. This is based on aggregated consumption of all utilities used at that site or within that organization. A further example is a grouping for facilities/sub-facilities/processes/mobile assets enabling users to group these items on a non-geographic basis. The user selected basis could be a cost center where each cost center is responsible for utility costs at several facilities and/or sub-facilities and/or processes and/or mobile assets. The cost center could cover departments, different tenants and other features in which the user is interested.

Another preferred feature of the invention is asset management. In this feature the user would enter types of utility consuming assets used in a particular building, for example generators, light bulbs and fittings, water heating and so on, along with specific information on each asset. The user would then be able to track assets.

The above data capture would enable the invention to conduct a virtual audit in which assets are assessed that are installed. A range of more efficient replacements are suggested that conform with the same general requirements and meet the same functionality. It would also report the level of savings that could be expected.

The invention could also provide maintenance management. The invention would interface with computerized maintenance management software systems to initially upload asset data and allow the desktop comparison of an existing asset with what is available in the market. The system would feed information back into the maintenance management system so that a maintenance manager can assess an asset's performance in terms of energy efficiency, as well as downtime or disruption to an organization and the costs of maintenance. Furthermore, as slight increases in energy consumption are almost always the first sign of an asset's impending failure, the invention would provide a report showing an early warning of imminent failure.

It is envisaged that one preferred form of the invention maintains data from several sources. This data could include information entered by the users about the assets over the Internet. This could be entered manually or electronically from computerized maintenance or asset management systems. Data could also include multiple data streams representing utility consumption data from retailers and metering providers, climate data or other external influences to a building or process from providers of this information, product information about assets from manufacturers and/or suppliers, financial information and/or transactions relating to the value of energy, greenhouse gas trading, waste streams and so on, placing of orders or instructions to purchase or provide goods and services, and/or a message brought by subscription that can be configured to suit the interests of various users and participants.

Examples of higher level reports include site reports, organization reports, alternative group reporting and exception reporting.

Site Reports

Site Reports include information aggregating the consumption of all supply level meters. This aggregation will then report on all energy consumption, CO₂ emissions, and costs.

Benchmark figures in square meters (m²) are aggregated for all facilities at the site so as to provide a benchmarked consumption/emissions indicator for the entire site. This figure is compared with similarly benchmarked figures (taking into account the energy intensity of the included facilities) for other sites run by this organization and other organizations.

Also it is expected that there will be aggregation of any Customized Indicator figures for all facilities at the site, where this customized indicator is being used for organization wide internal benchmarking. This figure is compared with similarly benchmarked figures (taking into account the energy intensity of the included facilities) for other sites run by this organization.

Organization Reports

Organization Reports include information aggregating the consumption of all supply level meters at each site run by the organization. This aggregation will then report on all energy consumption, CO2 emissions, and costs.

There is aggregation of the square meter benchmark figures for all facilities run by the organization so as to provide a benchmarked consumption/emissions indicator for the entire organization. This figure will be compared with similarly benchmarked figures for other organizations of the same type.

Also there is aggregation of any Customized Indicator figures for all facilities run by this organization, where this Customized Indicator is being used for organization wide internal benchmarking. This figure will not be comparable with any indicators from any other organization due to its customized nature, but will be able to be used for benchmarking performance of the organization over time (Targeting and Monitoring). As previously mentioned, these customized indicators could become standard system indicators where a number of organizations use similar indicators, or where a group of organizations indicate interest in adding a new system indicator.

Alternative Reporting

Alternative Grouping Reports include information aggregating the consumption of all facilities/sub-facilities included within this grouping (e.g., a department or cost center). This aggregation will then report on all energy consumption, CO₂ emissions, and costs.

There will be aggregation of the square meter benchmark figures for all facilities/sub-facilities within this alternative grouping so as to provide a benchmarked consumption/emissions indicator for the entire group. This figure is compared with similarly benchmarked figures (taking into account the energy intensity of the included facilities) for other groups run by this organization and other organizations.

Also it is envisaged that there be aggregation of any Customized Indicator figures for all facilities/sub-facilities included within this alternative group, where this customized indicator is being used for organization wide internal benchmarking. This figure will be compared with similarly benchmarked figures (taking into account the energy intensity of the included facilities) for other groups within this organization.

Exception Reporting

There may also be the automatic generation of exception reports that will send an email or emails to addresses entered by the user. The frequency of these reports will be dictated by the frequency with which the consumption data is input, i.e., monthly input of data could generate a report once a month, daily input—a daily report, etc.

The exceptions report will be generated by either of the two occurrences:

If the value charged per unit of consumed utility varies against what we would ordinarily expect to be charged;

If the level of consumption varies by a greater than expected percentage from historical records after benchmarking adjustments for climate fluctuations (where applicable, i.e., for example it is not appropriate to adjust the consumption of water within a building for climate, although it will be for gas fired heating systems). The user shall be responsible to selecting the percentage variation that would result in an exception report being generated.

Exceptions reports will also be generated on two levels. If after several reports identifying the same issue continue for a continuing period, e.g., for seven daily or two monthly occurrences, then an email will be sent to another address. The user will be responsible for entering this additional email address as well as for selecting the number of consecutive reports generated before this second tier of exception report will be generated.

Where multiple facility and/or process sites exist with limited sub-metering, when analyzing the results it is necessary to look at the results for all facilities and/or processes in combination rather than specific facilities or processes. If the results indicate that most facilities and/or processes are performing relatively poorly, then there may be a good business case to install additional metering equipment, or perform an energy audit, to determine exactly which facilities and/or processes are performing the poorest and would make the greatest gains from an in-depth energy audit.

The foregoing describes the invention including preferred forms thereof. Alterations and modifications as will be obvious to those skilled in the art are intended to be incorporated within the scope hereof, as defined by the accompanying claims.

1-18. (canceled)

19. A method of evaluating utility usage of an organization comprising:
storing in computer memory data representing one or more facilities operated by the organization;
storing in computer memory data representing one or more utility sources, each facility using one or more of the utility sources;
calculating the utility consumption from each utility source for at least one facility;
comparing the utility consumption of one or more of the facilities with the utility consumption of respective benchmark standards generated from similar facilities; and
generating a report detailing utility usage of one or more of the facilities, or part thereof, of the organization.

20. A method of evaluating utility usage of an organization as claimed in claim 19 further comprising:
storing in computer memory data representing one or more sites operated by the organization that are associated with one or more facilities;
calculating the utility consumption from each utility source for at least one site; and
generating a report detailing the utility usage of one or more of the sites.

21. A method of evaluating utility usage of an organization as claimed in claim 19 further comprising generating a report detailing the difference between utility consumption of one or more of the facilities and their respective benchmark standards.

22. A method of evaluating utility usage of an organization as claimed in claim 19 further comprising:
storing in computer memory data representing one or more mobile assets associated with the organization;
calculating the utility consumption from each utility source for at least one mobile asset; and
generating a report detailing the utility usage of one or more of the mobile assets of the organization.

23. A method of evaluating utility usage of an organization as claimed in claim 22 further comprising:
storing in computer memory data representing one or more sites operated by the organization that are associated with one or more mobile assets;
calculating the utility consumption from each utility source for at least one site; and
generating a report detailing the utility usage of one or more of the sites.

24. A method of evaluating utility usage of an organization as claimed in claim 22 further comprising:
comparing the utility consumption of one or more of the mobile assets with the utility consumption of respective benchmark standards generated from similar mobile assets; and
generating a report detailing the difference between the utility consumption of one or more of the mobile assets and their respective benchmark standards.

25. A method of evaluating utility usage of an organization comprising:
storing in computer memory data representing one or more processes operated by the organization;
storing in computer memory data representing one or more utility sources, each process using one or more of the utility sources;
calculating the utility consumption from each utility source for at least one process;
comparing the utility consumption of one or more of the processes with the utility consumption of respective benchmark standards generated from similar processes; and
generating a report detailing utility usage of one or more of the processes, or part thereof, of the organization.

26. A method of evaluating utility usage of an organization as claimed in claim 25 further comprising:
storing in computer memory data representing one or more sites operated by the organization that are associated with one or more processes;
calculating the utility consumption from each utility source for at least one site; and
generating a report detailing the utility usage of one or more of the sites.

27. A method of evaluating utility usage of an organization as claimed in claim 25 further comprising generating a report detailing the difference between utility consumption of one or more of the processes and their respective benchmark standards.

28. A method of evaluating utility usage of an organization as claimed in claim 25 further comprising:
storing in computer memory data representing one or more mobile assets associated with the organization;
calculating the utility consumption from each utility source for at least one mobile asset; and
generating a report detailing the utility usage of one or more of the mobile assets of the organization.

29. A method of evaluating utility usage of an organization as claimed in claim 28 further comprising:
storing in computer memory data representing one or more sites operated by the organization that are associated with one or more mobile assets;
calculating the utility consumption from each utility source for at least one site; and
generating a report detailing the utility usage of one or more of the sites.

30. A method of evaluating utility usage of an organization as claimed in claim 28 further comprising:
comparing the utility consumption of one or more of the mobile assets with the utility consumption of respective benchmark standards generated from similar mobile assets; and
generating a report detailing the difference between the utility consumption of one or more of the mobile assets and their respective benchmark standards.

31. A utility usage evaluation system comprising:
a client data store in which is stored data representing one or more facilities operated by an organization, and data representing one or more utility sources, each facility using one or more of the utility sources;
a benchmark database including data representing the utility consumption of respective benchmark standards with which the utility consumption of one or more of the facilities can be compared;
a utility consumption calculator configured to calculate the utility consumption from each utility source for at least one facility;
a utility consumption comparer configured to compare the utility consumption of one or more of the facilities with the utility consumption of respective benchmark standards generated from similar facilities; and
a report generator configured to generate a report detailing the utility usage of one or more of the facilities of the organization.

32. A utility usage valuation system as claimed in claim 31 wherein:
the client data store has stored in it data representing one or more sites operated by the organization that are associated with one or more facilities;
the utility consumption calculator is further configured to calculate the utility consumption from each utility source for at least one site; and
the report generator is configured to generate a report detailing the utility usage of one or more of the sites.

33. A utility usage evaluation system as claimed in claim 31 wherein the report generator is further configured to generate a report detailing the difference between utility consumption of one or more of the facilities and their respective benchmark standards.

34. A utility usage evaluation system as claimed in claim 31 wherein:
the client data store is further configured to store data representing one or more mobile assets associated with the organization;
the utility consumption calculator is further configured to calculate the utility consumption from each utility source for at least one mobile asset; and
the report generator is further configured to generate a report detailing the utility usage of one or more of the mobile assets of the organization.

35. A utility usage evaluation system as claimed in claim 34 wherein:
the client data store is further configured to store data representing one or more sites operated by the organization that are associated with one or more mobile assets;
the utility consumption calculator is configured to calculate the utility consumption from each utility source for at least one site; and
the report generator is configured to generate a report detailing the utility usage of one or more of the sites.

36. A utility usage evaluation system as claimed in claim 34 wherein:
the benchmark database includes data representing the utility consumption of respective benchmark standards generated from similar mobile assets;
the utility consumption comparer is configured to compare the utility consumption of one or more of the mobile assets with the respective benchmark standards stored in the benchmark database; and
the report generator is configured to generate a report detailing the difference between a utility consumption of one or more of the mobile assets and their respective benchmark standards.

37. A utility usage evaluation system comprising:
a client data store in which is stored data representing one or more processes operated by an organization, and data representing one or more utility sources, each process using one or more of the utility sources;
a benchmark database including data representing the utility consumption of respective benchmark standards with which the utility consumption of one or more of the processes can be compared;
a utility consumption calculator configured to calculate the utility consumption from each utility source for at least one process;
a utility consumption comparer configured to compare the utility consumption of one or more of the processes with the utility consumption of respective benchmark standards generated from similar processes; and
a report generator configured to generate a report detailing the utility usage of one or more of the processes of the organization.

38. A utility usage valuation system as claimed in claim 37 wherein:
the client data store has stored in it data representing one or more sites operated by the organization that are associated with one or more processes;
the utility consumption calculator is further configured to calculate the utility consumption from each utility source for at least one site; and
the report generator is configured to generate a report detailing the utility usage of one or more of the sites.

39. A utility usage evaluation system as claimed in claim 37 wherein the report generator is further configured to generate a report detailing the difference between utility consumption of one or more of the processes and their respective benchmark standards.

40. A utility usage evaluation system as claimed in claim 37 wherein:
the client data store is further configured to store data representing one or more mobile assets associated with the organization;
the utility consumption calculator is further configured to calculate the utility consumption from each utility source for at least one mobile asset; and
the report generator is further configured to generate a report detailing the utility usage of one or more of the mobile assets of the organization.

41. A utility usage evaluation system as claimed in claim 40 wherein:
the client data store is further configured to store data representing one or more sites operated by the organization that are associated with one or more mobile assets;
the utility consumption calculator is configured to calculate the utility consumption from each utility source for at least one site; and
the report generator is configured to generate a report detailing the utility usage of one or more of the sites.

42. A utility usage evaluation system as claimed in claim 40 wherein:
the benchmark database includes data representing the utility consumption of respective benchmark standards generated from similar mobile assets;
the utility consumption comparer is configured to compare the utility consumption of one or more of the mobile assets with the respective benchmark standards stored in the benchmark database; and
the report generator is configured to generate a report detailing the difference between a utility consumption of one or more of the mobile assets and their respective benchmark standards.

43. A computer-readable medium having computer-executable instructions for performing a method of evaluating utility usage of an organization, the method comprising:
storing in computer memory data representing one or more facilities operated by the organization;
storing in computer memory data representing one or more utility sources, each facility using one or more of the utility sources;
calculating the utility consumption from each utility source for at least one facility;
comparing the utility consumption of one or more of the facilities with the utility consumption of respective benchmark standards generated from similar facilities; and
generating a report detailing utility usage of one or more of the facilities, or part thereof, of the organization.

44. A computer-readable medium having computer-executable instructions for performing a method of evaluation utility usage of an organization, the method comprising:
storing in computer memory data representing one or more processes operated by the organization;
storing in computer memory data representing one or more utility sources, each process using one or more of the utility sources;
calculating the utility consumption from each utility source for at least one process;
comparing the utility consumption of one or more of the processes with the utility consumption of respective benchmark standards generated from similar processes; and
generating a report detailing utility usage of one or more of the processes, or part thereof, of the organization.

45. A utility usage evaluation system comprising:
means for storing in computer memory data representing one or more facilities operated by an organization;
means for storing in computer memory data representing one or more utility sources, each facility using one or more of the utility sources;
means for calculating the utility consumption from each utility source for at least one facility;
means for comparing the utility consumption of one or more of the facilities with the utility consumption of respective benchmark standards generated from similar facilities; and
means for generating a report detailing utility usage of one or more of the facilities, or part thereof, of the organization.

46. A utility usage evaluation system comprising:
means for storing in computer memory data representing one or more processes operated by an organization;
means for storing in computer memory data representing one or more utility sources, each process using one or more of the utility sources;
means for calculating the utility consumption from each utility source for at least one process;
means for comparing the utility consumption of one or more of the processes with the utility consumption of respective benchmark standards generated from similar processes;
means for generating a report detailing utility usage of one or more of the processes, or part thereof, of the organization; and
means for evaluating utility usage of an organization.
